(19) United States
(12) Patent Application Publication
(10) Pub. No.: US 2026/0190476 A1
(43) Pub. Date: Jul. 2, 2026

(54) STRUCTURE AND FORMATION METHOD OF SEMICONDUCTOR DEVICE WITH METAL GATE STACK

(71) Applicant: Taiwan Semiconductor Manufacturing Company, Ltd., Hsinchu (TW)

(72) Inventors: Kai-Yuan CHENG, Hsinchu County (TW); Chi HUANG, Changhua County (TW); Che-Chia HSU, Taoyuan city (TW)

(73) Assignee: Taiwan Semiconductor Manufacturing Company, Ltd., Hsinchu (TW)

(21) Appl. No.: 19/007,798

(22) Filed: Jan. 2, 2025

(51) Int. Cl. H10D 84/85; H10D 84/01

(52) U.S. Cl. CPC H10D 84/856; H10D 84/0167; H10D 84/017; H10D 84/0177; H10D 84/0188; H10D 84/851

(57) ABSTRACT

A semiconductor device structure and a formation method are provided. The method includes forming multiple sacrificial nanostructures and multiple semiconductor nanostructures laid out in an alternating manner on a substrate. The method also includes forming a first epitaxial structure on side edges of the semiconductor nanostructures and partially removing the first epitaxial structure to expose side edges of an upper group of the semiconductor nanostructures. The method further includes forming an isolation layer covering the first epitaxial structure and forming a second epitaxial structure on the side edges of the upper group of the semiconductor nanostructures. In addition, the method includes removing the sacrificial nanostructures and forming a metal gate stack wrapped around the semiconductor nanostructures. The metal gate stack has a continuous work function metal layer wrapped around each of the semiconductor nanostructures.

### BACKGROUND

The semiconductor integrated circuit (IC) industry has experienced rapid growth. Technological advances in IC materials and design have produced generations of ICs. Each generation has smaller and more complex circuits than the previous generation.

Over the course of IC evolution, functional density (i.e., the number of interconnected devices per chip area) has generally increased while geometric size (i.e., the smallest component (or line) that can be created using a fabrication process) has decreased. This scaling-down process generally provides benefits by increasing production efficiency and lowering associated costs.

However, these advances have increased the complexity of processing and manufacturing ICs. Since feature sizes continue to decrease, fabrication processes continue to become more difficult to perform. Therefore, it is a challenge to form reliable semiconductor devices at smaller and smaller sizes.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIGS. 1A-1B are top views of various stages of a process for forming a portion of a semiconductor device structure, in accordance with some embodiments.

FIGS. 2A-2C are cross-sectional views of various stages of a process for forming a portion of a semiconductor device structure, in accordance with some embodiments.

FIGS. 3A-3C are cross-sectional views of various stages of a process for forming a portion of a semiconductor device structure, in accordance with some embodiments.

FIGS. 4A-4S are cross-sectional views of various stages of a process for forming a portion of a semiconductor device structure, in accordance with some embodiments.

FIG. 5 is a cross-sectional view of a portion of a semiconductor device structure, in accordance with some embodiments.

FIG. 6 is a cross-sectional view of a portion of a semiconductor device structure, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Embodiments of the disclosure may relate to FinFET structure having fins. The fins may be patterned using any suitable method. For example, the fins may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in some embodiments, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fins. However, the fins may be formed using one or more other applicable processes.

Embodiments of the disclosure may relate to the gate all around (GAA) transistor structures. The GAA structure may be patterned using any suitable method. For example, the structures may be patterned using one or more photolithography processes, including double-patterning or multi-patterning processes. In some embodiments, double-patterning or multi-patterning processes combine photolithography and self-aligned processes, allowing patterns to be created that have, for example, pitches smaller than what is otherwise obtainable using a single, direct photolithography process. For example, in some embodiments, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

Some embodiments of the disclosure are described. Additional operations can be provided before, during, and/or after the stages described in these embodiments. Some of the stages that are described can be replaced or eliminated for different embodiments. Additional features can be added to the semiconductor device structure. Some of the features described below can be replaced or eliminated for different embodiments. Although some embodiments are discussed with operations performed in a particular order, these operations may be performed in another logical order.

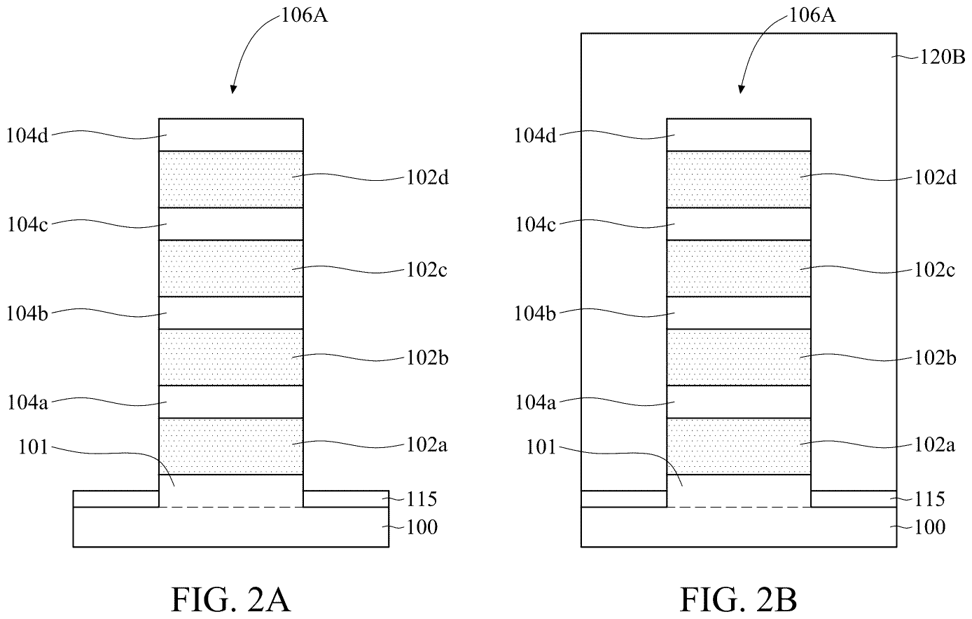

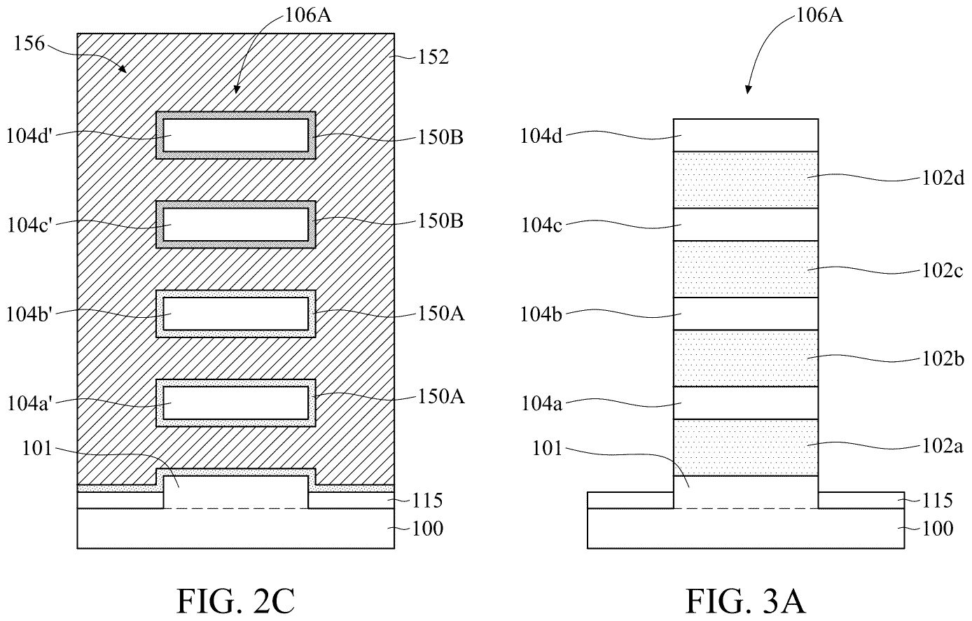

FIGS. 2A-2C are cross-sectional views of various stages of a process for forming a portion of a semiconductor device structure, in accordance with some embodiments. As shown in FIG. 2A, a semiconductor substrate 100 is received or provided. In some embodiments, the semiconductor substrate 100 is a bulk semiconductor substrate, such as a semiconductor wafer. The semiconductor substrate 100 may include silicon or other elementary semiconductor materials such as germanium. The semiconductor substrate 100 may be un-doped or doped (e.g., p-type, n-type, or a combination thereof). In some embodiments, the semiconductor substrate 100 includes an epitaxially grown semiconductor layer on a dielectric layer. The epitaxially grown semiconductor layer may be made of silicon germanium, silicon, germanium, one or more other suitable materials, or a combination thereof.

In some other embodiments, the semiconductor substrate 100 includes a compound semiconductor. For example, the compound semiconductor includes one or more III-V compound semiconductors having a composition defined by the formula Al_{X1}Ga_{X2}In_{X3}As_{Y1}P_{Y2}N_{Y3}Sb_{Y4}, where X1, X2, X3, Y1, Y2, Y3, and Y4 represent relative proportions. Each of them is greater than or equal to zero, and added together they equal 1. The compound semiconductor may include silicon carbide, gallium arsenide, indium arsenide, indium phosphide, one or more other suitable compound semiconductors, or a combination thereof. Other suitable substrate including II-VI compound semiconductors may also be used.

In some embodiments, the semiconductor substrate 100 is an active layer of a semiconductor-on-insulator (SOI) substrate. The SOI substrate may be fabricated using a separation by implantation of oxygen (SIMOX) process, a wafer bonding process, another applicable method, or a combination thereof. In some other embodiments, the semiconductor substrate 100 includes a multi-layered structure. For example, the semiconductor substrate 100 includes a silicon-germanium layer formed on a bulk silicon layer.

Afterwards, a semiconductor stack having multiple semiconductor layers is formed over the semiconductor substrate 100, in accordance with some embodiments. In some embodiments, the semiconductor stack includes multiple semiconductor layers 102a, 102b, 102c and 102d. The semiconductor stack also includes multiple semiconductor layers 104a, 104b, 104c and 104d. In some embodiments, the semiconductor layers 102a-102d and the semiconductor layers 104a-104d are laid out in an alternating manner, as shown in FIG. 2A.

In some embodiments, the semiconductor layers 102a-102d function as sacrificial layers that will be removed in a subsequent process to release the semiconductor layers 104a-104d. The semiconductor layers 104a-104d that are released may form multiple semiconductor nanostructures, which may serve as the channel structures of one or more transistors.

In some embodiments, the semiconductor layers 104a-104d that will be used to form channel structures are made of a material that is different than that of the semiconductor layers 102a-102d. In some embodiments, the semiconductor layers 104a-104d are made of or include silicon, another suitable material, or a combination thereof. In some embodiments, the semiconductor layers 102a-102d are made of or include silicon germanium. Due to the different compositions, different etching selectivity and/or different oxidation rates during subsequent processing may be achieved between the semiconductor layers 102a-102d and the semiconductor layers 104a-104d.

The present disclosure contemplates that the semiconductor layers 102a-102d and the semiconductor layers 104a-104d include any combination of semiconductor materials that can provide desired etching selectivity, desired oxidation rate differences, and/or desired performance characteristics (e.g., materials that maximize current flow).

Many variations and/or modifications can be made to embodiments of the disclosure. In some other embodiments, the semiconductor layers 104a-104d are made of or include III-V compound semiconductor materials, II-VI compound semiconductor material, another suitable material, or a combination thereof.

In some embodiments, each of the semiconductor layers 104a-104d has the same composition. However, many variations and/or modifications can be made to embodiments of the disclosure. In some other embodiments, the lower semiconductor layers (such as the semiconductor layers 104a and 104b) and the upper semiconductor layers (such as the semiconductor layers 104c and 104d) have different compositions.

In some embodiments, each of the semiconductor layers 104a-104d has the same thickness. However, many variations and/or modifications can be made to embodiments of the disclosure. In some other embodiments, the lower semiconductor layers (such as the semiconductor layers 104a and 104b) and the upper semiconductor layers (such as the semiconductor layers 104c and 104d) have different thicknesses.

In some embodiments, the semiconductor layers 102a-102d and 104a-104d are formed using multiple epitaxial growth operations. Each of the semiconductor layers 102a-102d and 104a-104d may be formed using a selective epitaxial growth (SEG) process, a CVD process (e.g., a vapor-phase epitaxy (VPE) process, a low-pressure chemical vapor deposition (LPCVD) process, and/or an ultra-high vacuum CVD (UHV-CVD) process), a molecular beam epitaxy process, one or more other applicable processes, or a combination thereof.

In some embodiments, the semiconductor layers 102a-102d and 104a-104d are grown in-situ in the same process chamber. In some embodiments, the growth of the semiconductor layers 102a-102d and 104a-104d are alternately and sequentially performed in the same process chamber to complete the formation of the semiconductor stack. In some embodiments, the vacuum of the process chamber is not broken before the epitaxial growth of the semiconductor stack is accomplished.

Afterwards, hard mask elements are formed over the semiconductor stack to assist in a subsequent patterning of the semiconductor stack. Each of the hard mask elements may include a first mask layer and a second mask layer. The first mask layer and the second mask layer may be made of different materials. One or more photolithography processes and one or more etching processes are used to pattern the semiconductor stack into multiple fin structures.

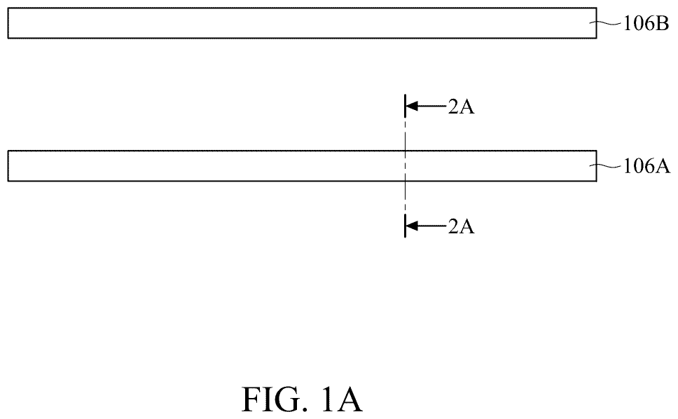

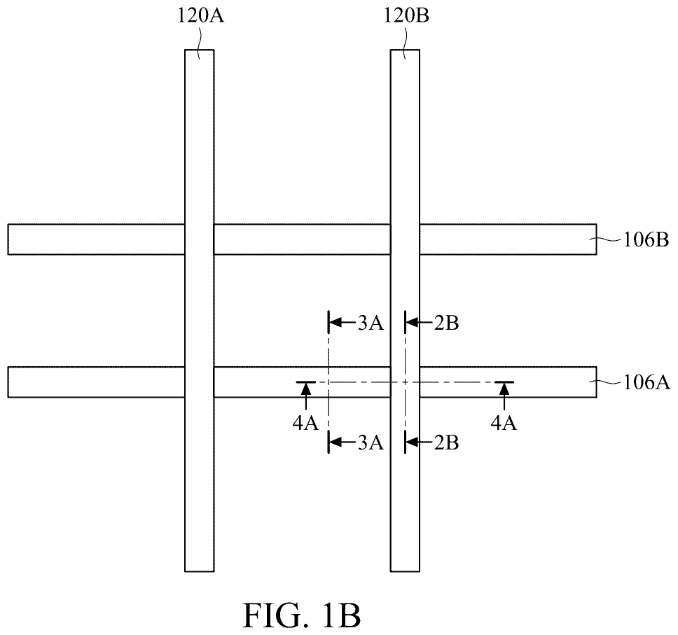

FIGS. 1A-1B are top views of various stages of a process for forming a portion of a semiconductor device structure, in accordance with some embodiments. As shown in FIG. 1A, multiple fin structures 106A and 106B are formed, in accordance with some embodiments. In some embodiments, FIG. 2A is a cross-sectional view of structure taken along the line 2A-2A in FIG. 1A.

The fin structures 106A and 106B may be patterned by any suitable method. For example, the fin structures may be patterned using one or more photolithography processes, including double-patterning or multi-patterning processes. Double-patterning or multi-patterning processes may combine photolithography and self-aligned processes, allowing patterns to be created that have, for example, pitches smaller than what is otherwise obtainable using a single, direct photolithography process.

The semiconductor stack is partially removed to form multiple fin structures (including fin structures 106A and 106B) and multiple trenches between these fin structures. Each of the fin structures 106A-106B may include portions of the semiconductor layers 102a-102d and 104a-104d and multiple semiconductor fins including semiconductor fin 101 as shown in FIG. 2A. The semiconductor substrate 100 may also be partially removed during the etching process that forms the fin structures. In some embodiments, the protruding portion of the semiconductor substrate 100 that remain form the semiconductor fin 101.

In some embodiments, the fin structures 106A and 106B are oriented lengthwise, as shown in FIG. 1A. In some embodiments, the extending directions of the fin structures 106A and 106B are substantially parallel to each other, as shown in FIG. 1A.

Afterwards, as shown in FIG. 2A, an isolation structure 115 is formed to surround lower portions of the fin structure 106A, in accordance with some embodiments. In some embodiments, one or more dielectric layers are deposited over the fin structures 106A and 106B and the semiconductor substrate 100. The dielectric layers may be made of or include silicon oxide, silicon oxynitride, borosilicate glass (BSG), phosphoric silicate glass (PSG), borophosphosilicate glass (BPSG), fluorinated silicate glass (FSG), low-k material, porous dielectric material, one or more other suitable materials, or a combination thereof. The dielectric layers may be deposited using a flowable chemical vapor deposition (FCVD) process, an atomic layer deposition (ALD) process, a chemical vapor deposition (CVD) process, one or more other applicable processes, or a combination thereof.

Afterwards, a planarization process is used to partially remove the dielectric layers. The hard mask elements (including the first mask layer and the second mask layer) used for defining the fin structures 106A and 106B may also function as a stop layer of the planarization process. The planarization process may include a chemical mechanical polishing (CMP) process, a grinding process, a dry polishing process, an etching process, one or more other applicable processes, or a combination thereof.

Afterwards, one or more etching back processes are used to partially remove the dielectric layers. As a result, the remaining portion of the dielectric layers forms the isolation structure 115. Upper portions of the fin structure 106A protrudes from the top surface of the isolation structure 115, as shown in FIG. 2A.

In some embodiments, the etching back process for forming the isolation structure 115 is carefully controlled to ensure that the topmost surface of the isolation structure 115 is positioned at a suitable height level, as shown in FIG. 2A. In some embodiments, the topmost surface of the isolation structure 115 is below the bottommost surface of the semiconductor layer 102a that functions as a sacrificial layer. The side edges of the bottommost sacrificial layer (i.e., the semiconductor layer 102a) are thus exposed without being covered by the isolation structure 115, thereby facilitating the subsequent removal process of the semiconductor layers 102a-102d.

Afterwards, the hard mask elements are removed. Alternatively, in some other embodiments, the hard mask elements are removed or consumed during the planarization process and/or the etching back process that forms the isolation structure 115.

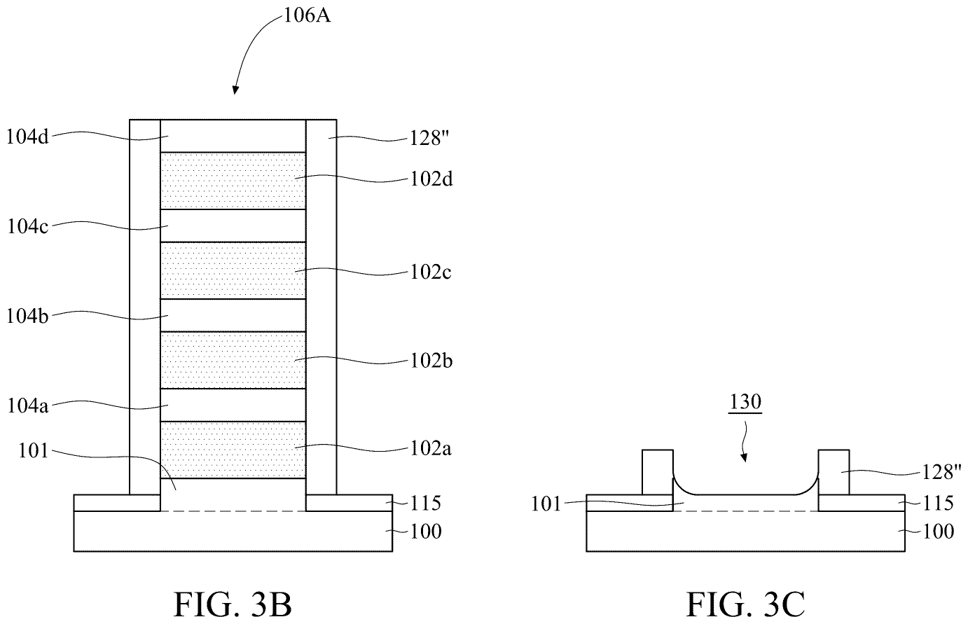

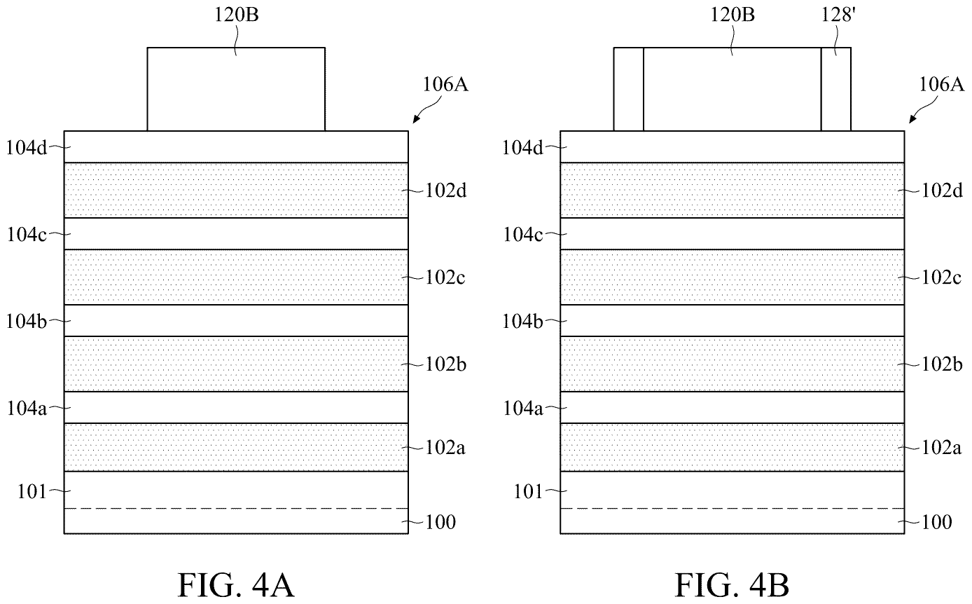

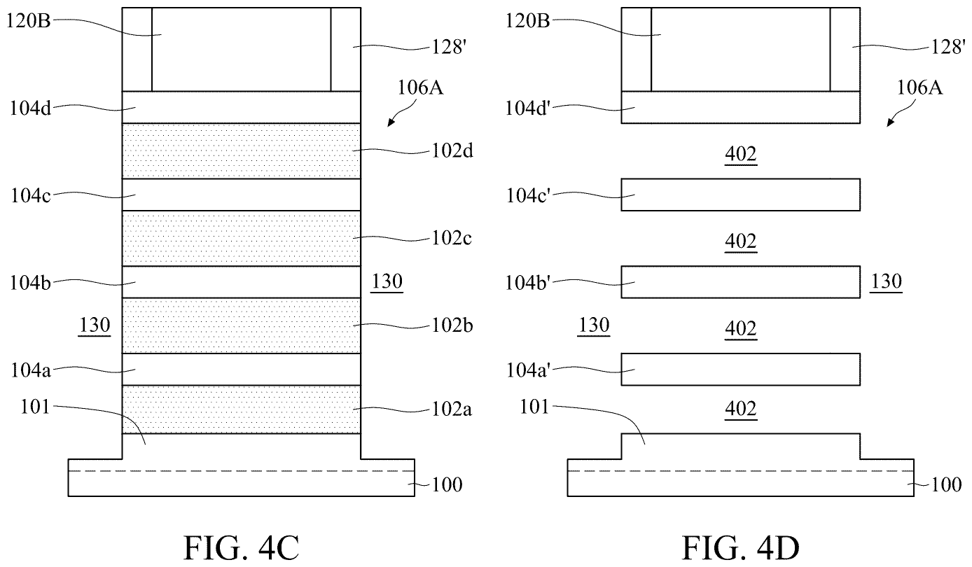

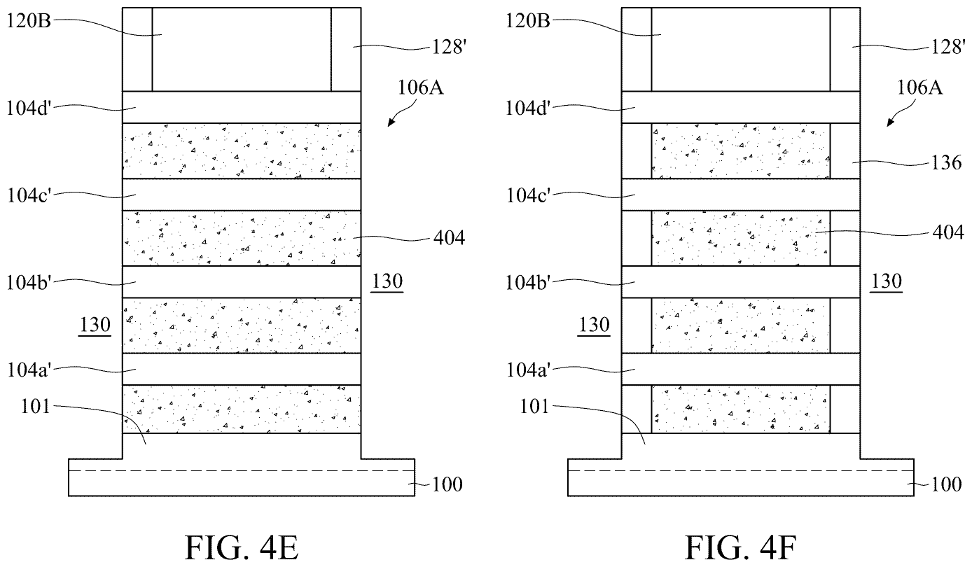

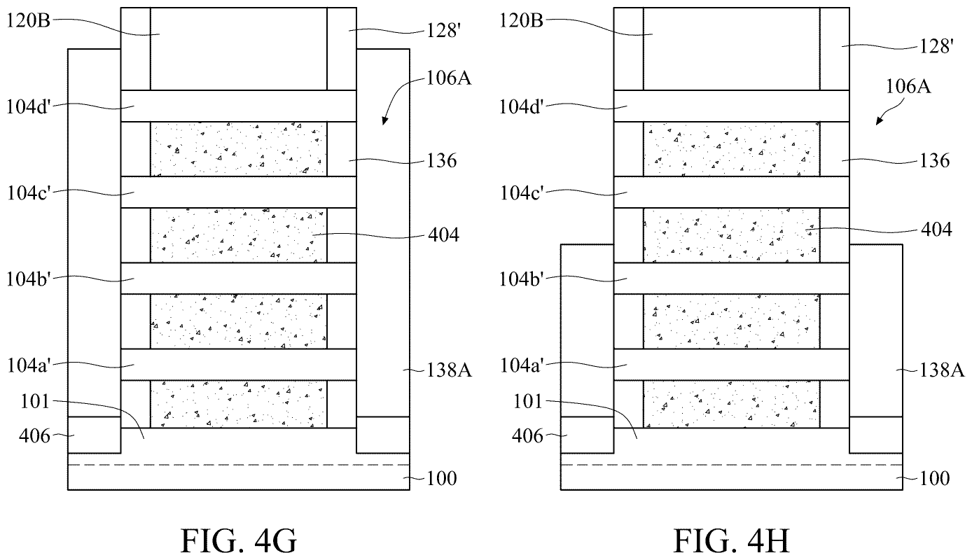

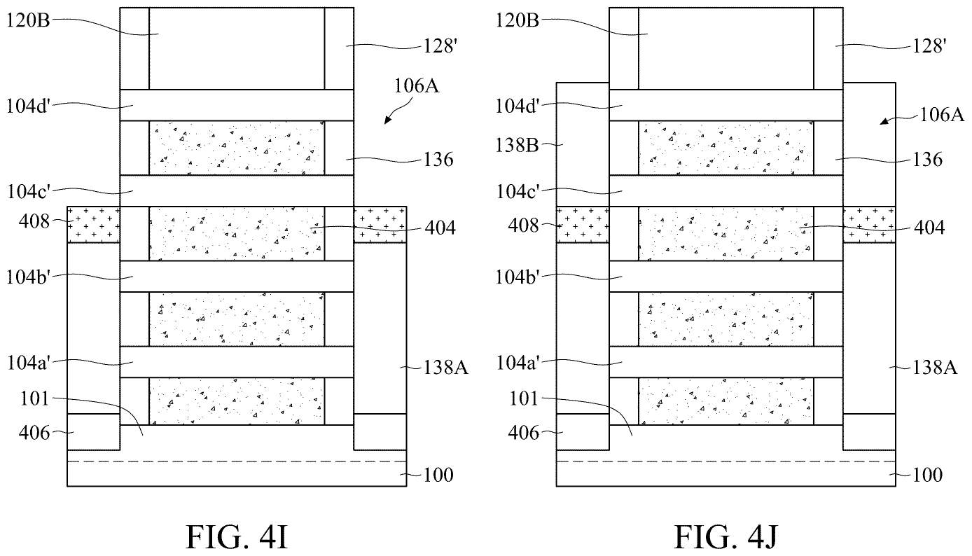

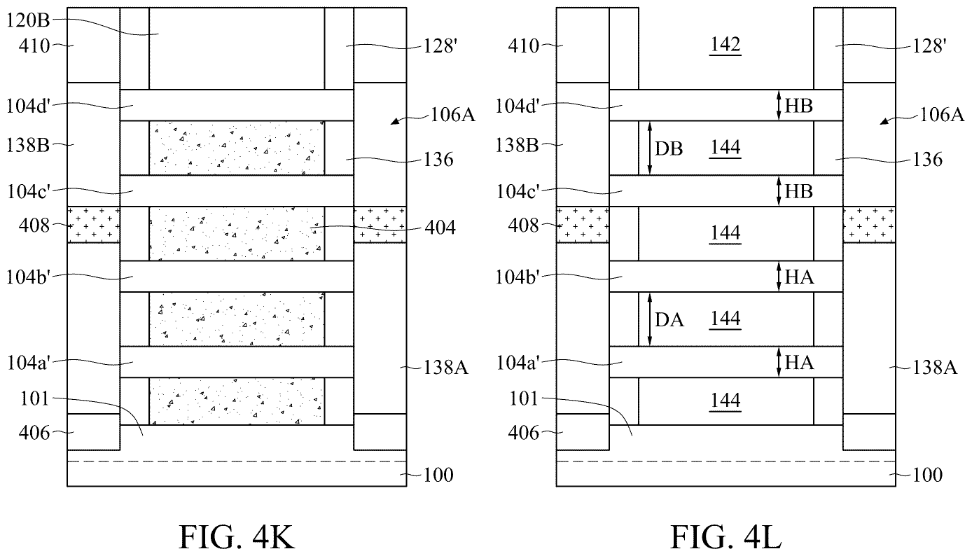

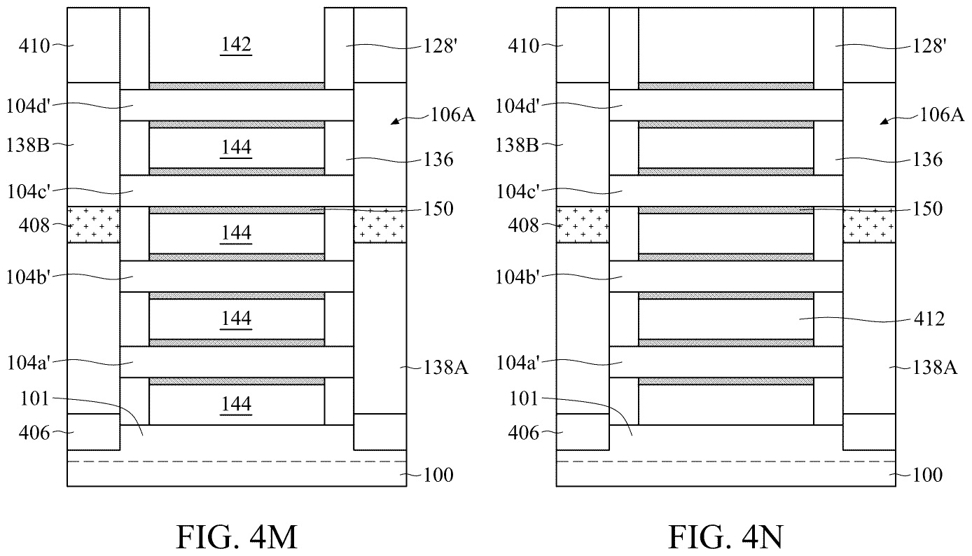

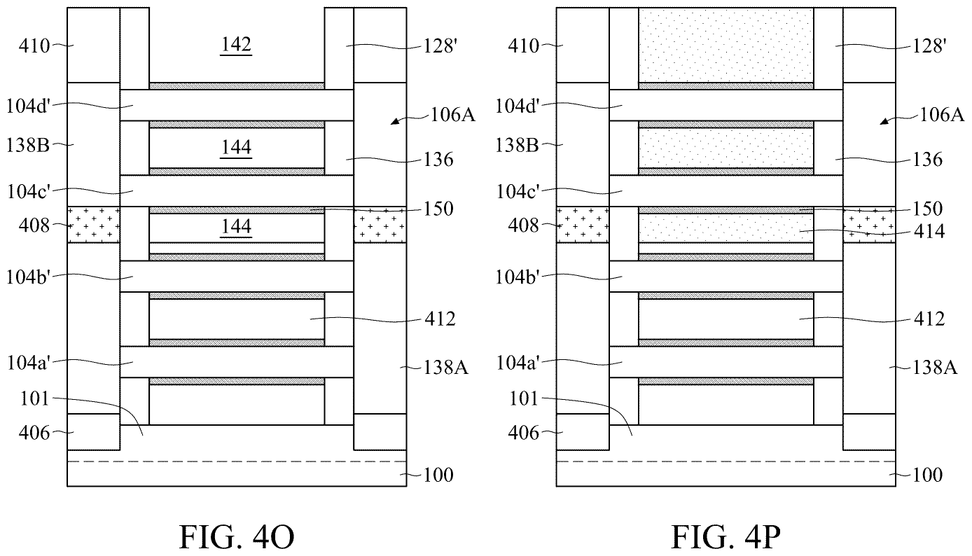

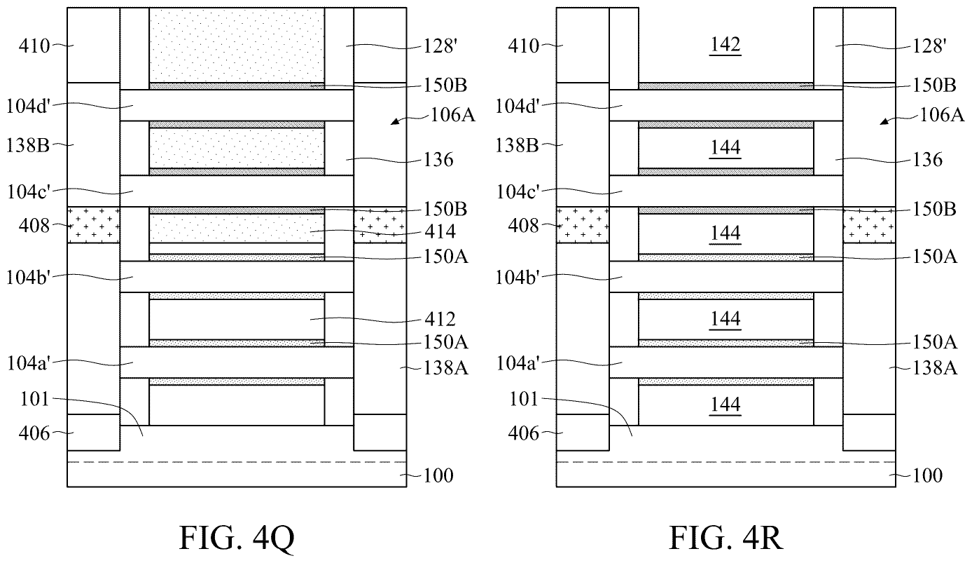

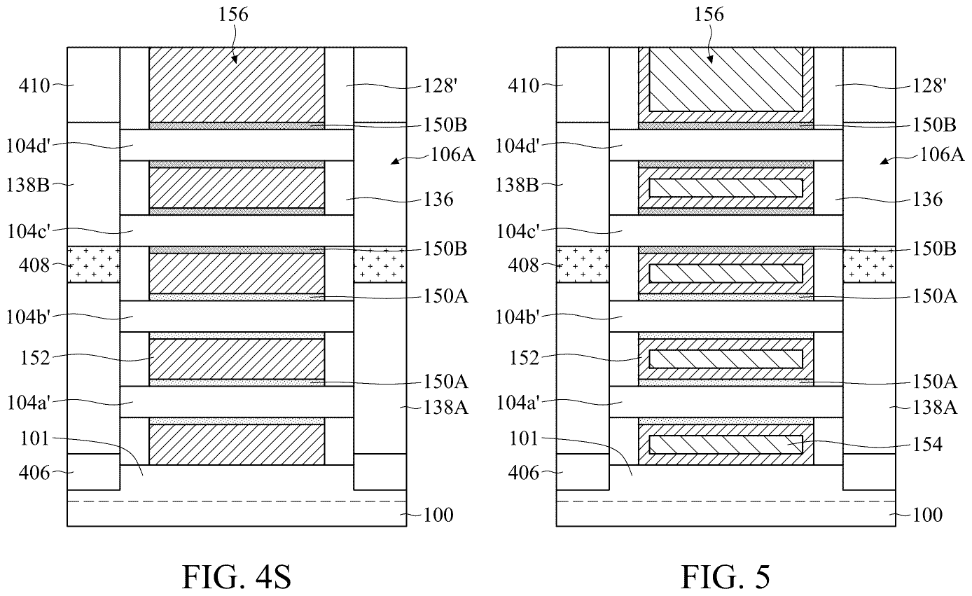

Afterwards, dummy gate stacks 120A and 120B are formed to extend across the fin structures 106A and 106B, as shown in FIG. 1B in accordance with some embodiments. In some embodiments, FIG. 2B is a cross-sectional view of the structure taken along the line 2B-2B in FIG. 1B. FIGS. 3A-3C are cross-sectional views of various stages of a process for forming portions of a semiconductor device structure, in accordance with some embodiments. In some embodiments, FIG. 3A is a cross-sectional view of the structure taken along the lines 3A-3A in FIG. 1B. FIGS. 4A-4S are cross-sectional views of various stages of a process for forming portions of a semiconductor device structure, in accordance with some embodiments. In some embodiments, FIG. 4A is a cross-sectional view of the structure taken along the lines 4A-4A in FIG. 1B.

As shown in FIG. 1B, the dummy gate stacks 120A and 120B partially cover and extend across the fin structures 106A and 106B, in accordance with some embodiments. As shown in FIG. 2B, the dummy gate stack 120B extends across and is wrapped around the fin structure 106A. As shown in FIG. 1B, other portions of the fin structures 106A and 106B are exposed without being covered by the dummy gate stack 120A and 120B.

In some embodiments, each of the dummy gate stacks 120A and 120B includes a dummy gate dielectric layer and a dummy gate electrode. The dummy gate dielectric layer may be made of or include silicon oxide or another suitable material. The dummy gate electrodes may be made of or include polysilicon or another suitable material.

In some embodiments, a dummy gate dielectric material layer and a dummy gate electrode layer are sequentially deposited over the isolation structure 115 and the fin structures 106A and 106B. The dummy gate dielectric material layer may be deposited using an ALD process, a CVD process, one or more other applicable processes, or a combination thereof. The dummy gate electrode layer may be deposited using a CVD process. Afterwards, the dummy gate dielectric material layer and the dummy gate electrode layer are patterned to form the dummy gate stacks 120A and 120B.

In some embodiments, hard mask elements are used to assist in the patterning process for forming the dummy gate stacks 120A and 120B. With the hard mask elements as an etching mask, one or more etching processes are used to partially remove the dummy gate dielectric material layer and the dummy gate electrode layer. As a result, remaining portions of the dummy gate dielectric material layer and the dummy gate electrode layer form the dummy gate stacks 120A and 120B.

As shown in FIGS. 3B and 4B, gate spacers 128′ and fin spacers 128″ are respectively formed along the sidewalls of the dummy gate stack 120B and the fin structure 106A, in accordance with some embodiments. One or more spacer layers are deposited over the dummy gate stack 120B and the fin structure 106A, in accordance with some embodiments. The spacer layers extend along the tops and sidewalls of the dummy gate stack 120B and the fin structure 106A.

The spacer layers may be made of or include silicon nitride, silicon carbide, silicon oxycarbide, carbon-containing silicon oxynitride, silicon oxide, another suitable material, or a combination thereof. The spacer layers may be sequentially deposited using a CVD process, an ALD process, a physical vapor deposition (PVD) process, another applicable process, or a combination thereof.

Afterwards, the spacer layers are partially removed, in accordance with some embodiments. One or more anisotropic etching processes may be used to partially remove the spacer layers. As a result, remaining portions of the spacer layers form the gate spacers 128′ and the fin spacers 128″, as shown in FIGS. 3B and 4B.

Afterwards, the fin structure 106A is partially removed to form recesses used for containing subsequently formed epitaxial structures. As shown in FIGS. 3C and 4C, the fin structure 106A is partially removed to form recesses 130, in accordance with some embodiments. The recesses 130 expose the side edges of the semiconductor layers 104a-104d on which epitaxial structures (such as source/drain structures) will subsequently be formed. A source/drain structure may refer to a source structure or a drain structure, individually or collectively, depending upon the context.

One or more etching processes may be used to form the recesses 130. In some embodiments, a dry etching process is used to form the recesses 130. Alternatively, a wet etching process may be used to form the recesses 130. In some embodiments, each of the recesses 130 extends into the fin structure 106A. In some embodiments, the recesses 130 further extend into the semiconductor fin 101, as shown in FIG. 3C. In some embodiments, during the formation of the recesses 130, the gate spacers 128′ and the fin spacers 128″ are also partially removed.

In some embodiments, the recesses 130 have substantially vertical sidewalls. In these cases, due to the profile of the recesses 130, an upper semiconductor layer (such as the semiconductor layer 104c) is substantially as wide as a lower semiconductor layer (such as the semiconductor layer 104b).

However, embodiments of the disclosure have many variations. In some other embodiments, each of the recesses 130 has slanted sidewalls. Upper portions of the recesses 130 are larger (or wider) than lower portions of the recesses 130. In these cases, due to the profile of the recesses 130, an upper semiconductor layer (such as the semiconductor layer 104c) is shorter than a lower semiconductor layer (such as the semiconductor layer 104b).

Afterwards, the semiconductor layers 102a-102d, which serve as sacrificial layers, are removed. As a result, the structure shown in FIG. 4D is formed, in accordance with some embodiments. One or more etching processes may be used to remove the semiconductor layers 102a-102d. After the removal of the semiconductor layers 102a-102d, multiple recesses 402 are formed, as shown in FIG. 4D. The remaining portions of the semiconductor layers 104a-104d that are released from the semiconductor layers 102a-102d form multiple semiconductor nanostructures 104a′, 104b′, 104c′, and 104d′, as shown in FIG. 4D. With the support of the dummy gate stack 120B that is wrapped around the fin structure 106A, the semiconductor nanostructures 104a′-104d′ are securely held in place.

As shown in FIG. 4E, multiple dielectric nanostructures 404 are formed in the recesses 402, in accordance with some embodiments. In some embodiments, the dielectric nanostructure is substantially free of germanium. Therefore, germanium is prevented from diffusing into the semiconductor nanostructures 104a′-104d′ that are nearby during the subsequent thermal processes. The quality and reliability of the semiconductor nanostructures 104a′-104d′ are significantly improved.

In some embodiments, a dielectric layer is deposited to overfill the recesses 402 and to surround the semiconductor nanostructures 104a′-104d′. The dielectric layer may also extend over the top and sidewalls of the dummy gate stack 120B. The dielectric layer may be made of an oxide material, a nitride material, another suitable material, or a combination thereof. The dielectric layer may be made of or include silicon oxide, silicon oxynitride, aluminum oxide, silicon nitride, another suitable material, or a combination thereof.

In some embodiments, the dielectric layer is a single layer. In some other embodiments, the dielectric layer includes multiple sub-layers. In some embodiments, the sub-layers of the dielectric layer are made of the same material. In some other embodiments, some of the sub-layers of the dielectric layer are made of different materials.

The dielectric layer may be deposited using a CVD process, an ALD process, a flowable chemical vapor deposition (FCVD) process, another applicable process, or a combination thereof. In some embodiments, the formation of the dielectric layer further involves one or more etching processes that are used to tune the profile of the deposited sub-layers of the dielectric layer.

Afterwards, the dielectric layer is partially removed using one or more etching processes. The portion of the dielectric layer outside of the recesses 402 are removed. As a result, the remaining portions of the dielectric layer form the multiple dielectric nanostructures 404, as shown in FIG. 4E.

As shown in FIG. 4F, inner spacers 136 are formed to cover the side edges of the dielectric nanostructures 404, in accordance with some embodiments. In some embodiments, the dielectric nanostructures 404 are partially removed to pull back the side edges of the dielectric nanostructures 404. One or more etching processes may be used to partially remove the dielectric nanostructures 404. As a result, the side edges of the dielectric nanostructures 404 retreat from the side edges of the semiconductor nanostructures 104a′-104d′. As a result, recesses are formed due to the lateral etching of the dielectric nanostructures 404. The recesses are used to contain the inner spacers 136 that will be formed later.

In some embodiment, the semiconductor nanostructures 104a′-104d′ are also slightly etched during the lateral etching of the dielectric nanostructures 404. As a result, edge portions of the semiconductor nanostructures 104a′-104d′ are partially etched and thus shrink. Each of the edge portions of the semiconductor nanostructures 104a′-104d′ may be thinner than the corresponding inner portion of the semiconductor nanostructures 104a′-104d′.

Embodiments of the disclosure are not limited thereto. Many variations and/or modifications can be made to embodiments of the disclosure. In some other embodiments, the semiconductor nanostructures 104a′-104d′ are substantially not etched during the lateral etching of the dielectric nanostructures 404. As a result, the edge portions of the semiconductor nanostructures 104a′-104d′ are substantially not shrunk. In some embodiments, each of the edge portions of the semiconductor nanostructures 104a′-104d′ is substantially as thick as the corresponding inner portion of the semiconductor nanostructures 104a′-104d′.

Afterwards, an insulating layer is deposited, in accordance with some embodiments. The insulating layer covers the dummy gate stack 120B and fills the recesses formed due to the lateral etching of the dielectric nanostructures 404. The insulating layer may be made of or include carbon-containing silicon nitride (SiCN), carbon-containing silicon oxynitride (SiOCN), carbon-containing silicon oxide (SiOC), silicon oxide, silicon nitride, another suitable material, or a combination thereof.

In some embodiments, the dielectric nanostructures 404 are made of silicon oxide, and the insulating layer is made of carbon-containing silicon oxynitride, silicon nitride, another suitable material, or a combination thereof. In some embodiments, the dielectric nanostructures 404 are made of silicon nitride, and the insulating layer is made of carbon-containing silicon oxynitride, silicon oxide, another suitable material, or a combination thereof. In some embodiments, the dielectric nanostructures 404 are made of silicon oxynitride, and the insulating layer is made of carbon-containing silicon oxynitride, another suitable material, or a combination thereof. In some embodiments, the dielectric nanostructures 404 are made of aluminum oxide, and the insulating layer is made of carbon-containing silicon oxynitride, another suitable material, or a combination thereof.

In some embodiments, the insulating layer is a single layer. In some other embodiments, the insulating layer includes multiple sub-layers. Some of the sub-layers may be made of different materials and/or contain different compositions. The insulating layer may be deposited using a CVD process, an ALD process, another applicable process, or a combination thereof.

Afterwards, an etching process is used to partially remove the insulating layer, in accordance with some embodiments. The portions of the insulating layer outside of the recesses are removed. The remaining portions of the insulating layer form the inner spacers 136, as shown in FIG. 4F. The etching process may include a dry etching process, a wet etching process, or a combination thereof.

The inner spacers 136 cover the side edges of the dielectric nanostructures 404, as shown in FIG. 4F. The inner spacers 136 may be used to prevent subsequently formed epitaxial structures (which function as source/drain structures, for example) from being damaged during a subsequent process for removing the dielectric nanostructures 404. In some embodiments, the inner spacers 136 are made of a low-k material that has a lower dielectric constant than that of silicon oxide. In these cases, the inner spacers 136 may also be used to reduce parasitic capacitance between the subsequently formed source/drain structures and the gate stacks. As a result, the operation speed of the semiconductor device structure is improved.

In some embodiments, after the etching process for forming the inner spacers 136, the side edges of the semiconductor nanostructures 104a′-104d′ are exposed by the recesses 130, as shown in FIG. 4F.

As shown in FIG. 4G, bottom isolation elements 406 are formed on the bottoms of the recesses 130, in accordance with some embodiments. The bottom isolation elements 406 may be used to further prevent leakage current between the semiconductor fin 101 and the epitaxial structures that will be formed on the bottom isolation elements 406.

In some embodiments, the bottom isolation elements 406 are made of or include a dielectric material. The dielectric material may include silicon oxide, silicon nitride, carbon-containing silicon nitride, carbon-containing silicon oxynitride, carbon-containing silicon oxide, aluminum oxide, hafnium oxide, another suitable material, or a combination thereof. The formation of the bottom isolation elements 406 may involve one or more deposition processes and one or more etching processes.

However, embodiments of the disclosure are not limited thereto. Many variations and/or modifications can be made to embodiments of the disclosure. In some other embodiments, the bottom isolation elements 406 are not formed.

Afterwards, as shown in FIG. 4G, epitaxial structures 138A are formed on the bottom isolation elements 406 and the side edges of the semiconductor nanostructures 104a′-104d′, in accordance with some embodiments. In some embodiments, the top surfaces of the epitaxial structures 138A are higher than the top surface of the semiconductor nanostructure 104d′. In some other embodiments, the epitaxial structures 138A are substantially as high as the top surface of the semiconductor nanostructure 104d′.

In some embodiments, the epitaxial structures 138A connect to the semiconductor nanostructures 104a′-104d′. Each of the semiconductor nanostructures 104a′-104d′ is sandwiched between the epitaxial structures 138A. In some embodiments, the epitaxial structures 138A have lightly doped portions adjacent to the semiconductor nanostructures 104a′-104d′. The dopant concentration of the lightly doped portions is lower than other portions of the epitaxial structures 138A.

In some embodiments, the epitaxial structures 138A are p-type doped regions. The epitaxial structures 138A may include epitaxially grown silicon germanium (SiGe), epitaxially grown silicon, or another suitable epitaxially grown semiconductor material. P-type dopants may include boron, another suitable element, or a combination thereof.

However, embodiments of the disclosure are not limited thereto. In some other embodiments, the epitaxial structures 138A are n-type doped regions. The epitaxial structures 138A may include epitaxially grown silicon, epitaxially grown silicon carbide (SiC), epitaxially grown germanium, or another suitable epitaxially grown semiconductor material. N-type dopants may include phosphor, arsenic, another suitable element, or a combination thereof.

In some embodiments, the epitaxial structures 138A are doped in-situ during their epitaxial growth. The initial reaction gas mixture for forming the epitaxial structures 138A contains dopants. In some embodiments, the epitaxial structures 138A are further exposed to one or more annealing processes to activate the dopants. For example, a rapid thermal annealing process is used.

In some embodiments, the formation of the epitaxial structures 138A that involves the thermal processes is performed after the semiconductor layers 102a-102d are replaced with the dielectric nanostructures 404. Therefore, germanium from the semiconductor layers 102a-102d is prevented from diffusing into the nearby semiconductor nanostructures 104a′-104d′ during the formation of the epitaxial structures 138A. The semiconductor nanostructures 104a′-104d′ may thus have a low atomic concentration of germanium impurities, enhancing the quality and reliability of the semiconductor nanostructures 104a′-104d′.

As shown in FIG. 4H, the epitaxial structures 138A are partially removed, in accordance with some embodiments. As a result, the epitaxial structures 138A are lowered, and the side edges of an upper group of the semiconductor nanostructures 104a′-104d′ are exposed. As shown in FIG. 4H, the side edges of the semiconductor nanostructures 104c′ and 104d′ are exposed. One or more etching processes may be used to partially remove the epitaxial structures 138A.

As shown in FIG. 4I, an isolation layer 408 is formed over the epitaxial structures 138A, in accordance with some embodiments. The isolation layer 408 may be used to prevent a subsequently formed second epitaxial structures from growing on the epitaxial structures 138A. The isolation layer 408 may cover and laterally surround the epitaxial structures 138A.

In some embodiments, an insulating layer is deposited over the epitaxial structures 138A, the fin structure 106A, and the dummy gate stack 120B. The insulating layer may be made of a dielectric material that is different than the inner spacers 136 and the gate spacers 128′. For example, the insulating layer may be made of or include silicon oxide, silicon oxynitride, aluminum oxide, another suitable material, or a combination thereof. The insulating layer may be deposited using a CVD process, an ALD process, another applicable process, or a combination thereof.

Afterwards, one or more etching processes are used to partially remove the insulating layer. As a result, the remaining portions of the insulating layer form the isolation layer 408. Due to the partial removal of the insulating layer, the side edges of the semiconductor nanostructures 104c′ and 104d′ are exposed.

As shown in FIG. 4J, epitaxial structures 138B are formed over the isolation layer 408 and the side edges of the semiconductor nanostructures 104c′-104d′, in accordance with some embodiments. In some embodiments, the top surfaces of the epitaxial structures 138B are higher than the top surface of the semiconductor nanostructure 104d′. In some other embodiments, the epitaxial structures 138B are substantially as high as the top surface of the semiconductor nanostructure 104d′.

In some embodiments, the epitaxial structures 138B connect to the semiconductor nanostructures 104c′-104d′. Each of the semiconductor nanostructures 104c′-104d′ is sandwiched between the epitaxial structures 138B. In some embodiments, the epitaxial structures 138B have lightly doped portions adjacent to the semiconductor nanostructures 104c′-104d′. The dopant concentration of the lightly doped portions is lower than other portions of the epitaxial structures 138B.

In some embodiments, the epitaxial structures 138B and 138A are oppositely doped. In some embodiments, the epitaxial structures 138A are n-type doped regions, and the epitaxial structures 138B are p-type doped regions. The epitaxial structures 138B may include epitaxially grown silicon germanium (SiGe), epitaxially grown silicon, or another suitable epitaxially grown semiconductor material. P-type dopants may include boron, another suitable element, or a combination thereof.

However, embodiments of the disclosure are not limited thereto. In some other embodiments, the epitaxial structures 138A are p-type doped regions, and the epitaxial structures 138B are n-type doped regions. The epitaxial structures 138B may include epitaxially grown silicon, epitaxially grown silicon carbide (SiC), epitaxially grown germanium, or another suitable epitaxially grown semiconductor material. N-type dopants may include phosphor, arsenic, another suitable element, or a combination thereof.

In some embodiments, the epitaxial structures 138B are doped in-situ during their epitaxial growth. The initial reaction gas mixture for forming the epitaxial structures 138B contains dopants. In some embodiments, the epitaxial structures 138B are further exposed to one or more annealing processes to activate the dopants. For example, a rapid thermal annealing process is used.

As shown in FIG. 4K, a dielectric layer 410 are formed over the epitaxial structures 138B and the dummy gate stack 120B, in accordance with some embodiments. The dielectric layer 410 may be made of or include silicon oxide, silicon oxynitride, borosilicate glass (BSG), phosphoric silicate glass (PSG), borophosphosilicate glass (BPSG), fluorinated silicate glass (FSG), low-k material, porous dielectric material, another suitable material, or a combination thereof. The dielectric layer 410 may be deposited using an FCVD process, a CVD process, an ALD process, another applicable process, or a combination thereof.

Afterwards, as shown in FIG. 4L, the dummy gate stack 120B and the dielectric nanostructures 404 are removed to form a trench 142 and recesses 144, in accordance with some embodiments. As a result, the semiconductor nanostructures 104a′-104d′ are exposed. One or more etching processes may be used to remove the dummy gate stack 120B and the dielectric nanostructures 404.

Due to high etching selectivity, the semiconductor nanostructures 104a′-104d′ are slightly (or substantially not) etched. The semiconductor nanostructures 104a′-104d′ suspended over the semiconductor fin 101 may function as the channel structures of transistors. In some other embodiments, the etchant used for removing the dielectric nanostructures 404 also slightly removes the semiconductor nanostructures 104a′-104d′. As a result, the obtained semiconductor nanostructures 104a′-104d′ become thinner after the removal of the dielectric nanostructures 404. In some embodiments, the inner portion of each of the semiconductor nanostructures 104a′-104d′ is thinner than the edge portions of the semiconductor nanostructures 104a′-104d′ since the edge portions are surrounded by other elements and thus are prevented from being reached and etched by the etchant.

However, embodiments of the disclosure are not limited thereto. Many variations and/or modifications can be made to embodiments of the disclosure. In some embodiments, the inner portion of each of the semiconductor nanostructures 104a′-104d′ is substantially as thick as the edge portions of the semiconductor nanostructures 104a′-104d′. In some other embodiments, the inner portion of each of the semiconductor nanostructures 104a′-104d′ is slightly thicker than the edge portions of the semiconductor nanostructures 104a′-104d′.

After the removal of the dielectric nanostructures 404 (which function as sacrificial layers), the recesses 144 are formed. The recesses 144 connect to the trench 142 and surround each of the semiconductor nanostructures 104a′-104d′. As shown in FIG. 4L, even with the formation of recesses 144 between the semiconductor nanostructures 104a′-104d′, the semiconductor nanostructures 104a′-104d′ remain supported by the neighboring elements, including the epitaxial structures 138A and 138B and the inner spacers 136. Therefore, after the removal of the dummy gate stack 120B and the dielectric nanostructures 404, the released semiconductor nanostructures 104a′-104d′ remain held in place.

As shown in FIG. 4L, each of the semiconductor nanostructures 104a′-104b′ that are next to the epitaxial structures 138A has a thickness HA, and each of the semiconductor nanostructures 104c′-104d′ that are next to the epitaxial structures 138B has a thickness HB. In some embodiments, the thicknesses HA and HB are substantially the same. In some embodiments, the thicknesses HA and HB are different. In some embodiments, the semiconductor nanostructures that are next to n-type doped epitaxial structures are thinner than the semiconductor nanostructures that are next to p-type doped epitaxial structures. The thickness HA may be in a range from about 2 nm to about 5 nm. The thickness HB may be approximately 0.2 nm to 1 nm thinner than the thickness HA.

As shown in FIG. 4L, the semiconductor nanostructures 104a′ and 104b′ are separated from each other by a distance DA, and the semiconductor nanostructures 104c′ and 104d′ are separated from each other by a distance DB. In some embodiments, the distances DA and DB are substantially the same. In some other embodiments, the distances DA and DB are different. The difference between the distances DA and DB may be in a range from about 0.3 nm to about 5 nm. The distance DA may be in a range from about 5 nm to about 12 nm.

During the removal of the dielectric nanostructures 404 (which function as sacrificial layers), the inner spacers 136 protect the epitaxial structures 138A and 138B from being etched or damaged. The quality and reliability of the semiconductor device structure are ensured.

As shown in FIG. 4M, gate dielectric layers 150 are deposited on the surfaces of the semiconductor nanostructures 104a′-104d′, in accordance with some embodiments. In some embodiments, the gate dielectric layer 150 is made of or includes a dielectric material with high dielectric constant (high-K). The gate dielectric layers 150 may be made of or include hafnium oxide, zirconium oxide, aluminum oxide, hafnium dioxide-alumina alloy, hafnium silicon oxide, hafnium silicon oxynitride, hafnium tantalum oxide, hafnium titanium oxide, hafnium zirconium oxide, one or more other suitable high-K materials, or a combination thereof. The gate dielectric layers 150 may be deposited using an ALD process, a CVD process, another applicable process, or a combination thereof. In some embodiments, the gate dielectric layers 150 are selectively grown on the surfaces of the semiconductor nanostructures 104a′-104d′.

In some embodiments, before the formation of the gate dielectric layers 150, interfacial layers are formed on the surfaces of the semiconductor nanostructures 104a′-104d′. The interfacial layers are thin layers made of, for example, silicon oxide. In some embodiments, the interfacial layers are formed by applying an oxidizing agent to the surfaces of the semiconductor nanostructures 104a′-104d′. For example, a hydrogen peroxide-containing liquid may be provided or applied to the surfaces of the semiconductor nanostructures 104a′-104d′ so as to form the interfacial layers.

As shown in FIG. 4N, a blocking layer 412 is deposited to fill the recesses 144 and the trench 142, in accordance with some embodiments. The blocking layer 412 may be made of or include aluminum oxide, silicon nitride, silicon oxide, photoresist, another suitable material, or a combination thereof. The blocking layer 412 may be deposited using a CVD process, an ALD process, a FCVD process, another applicable process, or a combination thereof.

As shown in FIG. 4O, the blocking layer 412 is partially removed, in accordance with some embodiments. As a result, the gate dielectric layers 150 that are wrapped around the semiconductor nanostructures 104c′-104d′ are exposed. The gate dielectric layers 150 that are wrapped around the semiconductor nanostructures 104a′-104b′ remain covered by the blocking layer 412. One or more etching processes may be used to etch back the blocking layer 412.

As shown in FIG. 4P, a modifying layer 414 is formed to cover the gate dielectric layers 150 that are wrapped around the semiconductor nanostructures 104c′-104d′, in accordance with some embodiments. The modifying layer 414 may be used to modify the composition of the gate dielectric layers 150, so as to fine-tune the threshold voltage of the semiconductor nanostructures 104c′-104d′. The modifying layer 414 may be made of or include metal oxide and or metal nitride where metal elements include lanthanum, aluminum, strontium, erbium, yttrium, gallium, indium, zinc, another suitable material, or a combination thereof.

As shown in FIG. 4Q, a thermal operation is used to heat the modifying layer 414 and the gate dielectric layers 150 surrounded by the modifying layer 414, in accordance with some embodiments. As a result, some modifying dopants from the modifying layer 414 are introduced into the gate dielectric layers 150 to modify or dope the gate dielectric layers 150. As a result, upper gate dielectric layers 150B that have been modified or doped are formed.

As shown in FIG. 4Q, the gate dielectric layers 150 that are wrapped around the semiconductor nanostructures 104a′-104b′ are covered by the blocking layer 412 form lower gate dielectric layers 150A. During the formation of the modified gate dielectric layer 150B, the gate dielectric layers 150 is prevented from being modified by the modifying layer 414 due to the blocking layer 412. The gate dielectric layers 150A and 150B with different compositions may assist in fine-tuning the threshold voltages of the semiconductor nanostructures 104a′-104b′ and 104c′-104d′, respectively.

Many variations and/or modifications can be made to embodiments of the disclosure. In some other embodiments, the blocking layer 412 also function as a modifying layer. In these cases, the gate dielectric layers 150A are also modified gate dielectric layers.

As shown in FIG. 4R, the modifying layer 414 and the blocking layer 412 are removed, in accordance with some embodiments. The gate dielectric layers 150A and 150B are thus exposed. One or more etching processes may be used to remove the modifying layer 414 and the blocking layer 412. In some embodiments, each of the gate dielectric layers 150A is substantially as thick as each of the gate dielectric layers 150B. In some other embodiments, each of the gate dielectric layers 150A is thicker than each of the gate dielectric layers 150B. In some other embodiments, each of the gate dielectric layers 150A is thinner than each of the gate dielectric layers 150B.

As shown in FIG. 4S, a work function metal layer 152 is formed to fill the trench 142 and the recesses 144, in accordance with some embodiments. The work function metal layer 152 and the gate dielectric layers 150A and 150B together form a metal gate stack 156. In some embodiments, the work function metal layer 152 is a single layer that is continuously wrapped around the semiconductor nanostructures 104a′-104b′ that are next to the epitaxial structures 138A and the semiconductor nanostructures 104c′-104d′ that are next to the epitaxial structures 138B.

The work function metal layer 152 and the gate dielectric layers 150A may work together to fine-tune the desired threshold voltage of the semiconductor nanostructures 104a′-104b′. The work function metal layer 152 and the gate dielectric layers 150B may work together to fine-tune the desired threshold voltage of the semiconductor nanostructures 104c′-104d′.

The work function metal layer 152 may include metal, metal carbide, metal nitride, another suitable material, or a combination thereof. The work function metal layer 152 may be made of or include tantalum nitride, tungsten nitride, titanium nitride, TiAlC, TiAlO, TiAlN, hafnium, zirconium, titanium, tantalum, aluminum, metal carbides (e.g., hafnium carbide, zirconium carbide, titanium carbide, aluminum carbide), aluminides, ruthenium, palladium, platinum, cobalt, nickel, conductive metal oxides, or a combination thereof. In some embodiments, the work function metal layer 152 is a titanium-containing layer.

The work function metal layer 152 may be deposited using an ALD process, a CVD process, a PVD process, an electroplating process, an electrochemical plating process, another applicable process, or a combination thereof.

Afterwards, a planarization process is performed to remove the portions of the work function metal layer 152 outside of the trench 142 and the recesses 144, in accordance with some embodiments. As a result, the metal gate stack 156 shown in FIG. 4S is formed. FIG. 2C shows another cross-sectional view of the metal gate stack 156 and the semiconductor nanostructures 104a′-104d′.

In some embodiments, the upper portion of the work function metal layer 152 is not removed and replaced with another work function metal layer. No metal patterning process need to be performed within a high aspect ratio space. The high process loading from forming different work function metal in NFET device and PFET device is prevented. The process loading is greatly reduced. The threshold voltage impact due to the stacking between different work function metal layers and the boundary effect between different work function metal layers are also prevented. The performance and reliability of the semiconductor device structure are significantly improved.

Many variations and/or modifications can be made to embodiments of the disclosure. In some other embodiments, two or more work function metal layers are formed to continuous wrap around the semiconductor nanostructures 104a′-104d′.

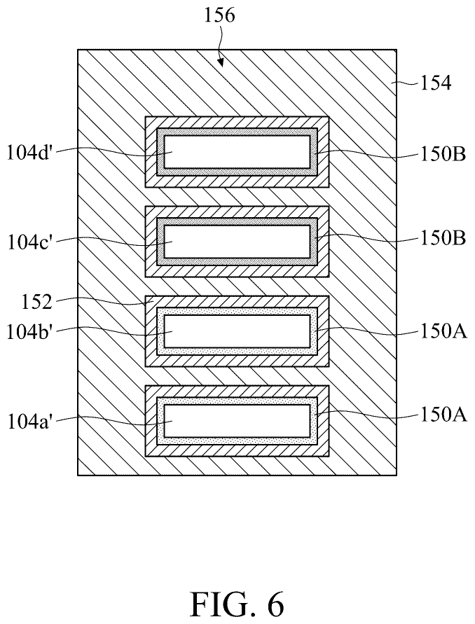

FIG. 5 is a cross-sectional view of a portion of a semiconductor device structure, in accordance with some embodiments. FIG. 6 is a cross-sectional view of a portion of a semiconductor device structure, in accordance with some embodiments. As shown in FIGS. 5 and 6, a structure that is similar to that shown in FIGS. 4S and 2C is formed. In some embodiments, a second work function metal layer 154 is formed after the formation of the work function metal layer 152. The work function metal layer 152, the second work function metal layer 154, and the gate dielectric layers 150A may work together to fine-tune the desired threshold voltage of the semiconductor nanostructures 104a′-104b′. The work function metal layer 152, the second work function metal layer 154, and the gate dielectric layers 150B may work together to fine-tune the desired threshold voltage of the semiconductor nanostructures 104c′-104d′.

Many variations and/or modifications can be made to embodiments of the disclosure. In some embodiments, there are two channel structures (such as the semiconductor nanostructures 104a′-104b′) formed between the nearby epitaxial structures 138A. However, embodiments of the disclosure are not limited thereto. Many variations and/or modifications can be made to embodiments of the disclosure. In some embodiments, the total number of semiconductor nanostructures between the nearby epitaxial structures 138A is greater than two. In some other embodiments, there is only one semiconductor nanostructure between the nearby epitaxial structures 138A. The total number of semiconductor nanostructures (or channel structures) between the nearby epitaxial structures 138A may be fine-tuned to meet requirements. For example, the total number of semiconductor nanostructures between the nearby epitaxial structures 138A may be between 1 and 10. The semiconductor nanostructures may have many applicable profiles. The semiconductor nanostructures may include nanosheets, nanowires, or other suitable nanostructures.

In some embodiments, the total number of semiconductor nanostructures between the nearby epitaxial structures 138A is equal to the total number of semiconductor nanostructures between the nearby epitaxial structures 138B. However, embodiments of the disclosure are not limited thereto. Many variations and/or modifications can be made to embodiments of the disclosure. In some other embodiments, the total number of semiconductor nanostructures between the nearby epitaxial structures 138A is less than the total number of semiconductor nanostructures between the nearby epitaxial structures 138B. In some other embodiments, the total number of semiconductor nanostructures between the nearby epitaxial structures 138A is greater than the total number of semiconductor nanostructures between the nearby epitaxial structures 138B.

Embodiments of the disclosure form a semiconductor device structure with multiple stacked semiconductor nanostructures. A lower group of the semiconductor nanostructures are sandwiched between first epitaxial structures, and an upper group of the semiconductor nanostructures are sandwiched between second epitaxial structures. The first epitaxial structures and the second epitaxial structures are oppositely doped. A metal gate stack is formed to wrap around each of the semiconductor nanostructures. Vertically stacked NMOS device and PMOS device are thus formed. The metal gate stack has the same work function metal layer continuously wrapped around each of the semiconductor nanostructures. The high process loading from forming different work function metal in NFET device and PFET device is prevented. The process loading is greatly reduced. This also greatly enhances the performance and reliability of the semiconductor device structure.

In accordance with some embodiments, a method for forming a semiconductor device structure is provided. The method includes forming a fin structure over a substrate, and the fin structure has multiple sacrificial nanostructures and multiple semiconductor nanostructures laid out in an alternating manner. The method also includes forming a dummy gate stack extending across a portion of the fin structure and partially removing the fin structure to form a recess exposing side edges of the sacrificial nanostructures and the semiconductor nanostructures. The method further includes forming a first epitaxial structure on the side edges of a lower group of the semiconductor nanostructures and forming an isolation layer over the first epitaxial structure. In addition, the method includes forming a second epitaxial structure on the side edges of an upper group of the semiconductor nanostructures. The second epitaxial structure and the first epitaxial structure are oppositely doped. The method includes removing the dummy gate stack and the sacrificial nanostructures to expose the semiconductor nanostructures and forming a metal gate stack wrapped around the semiconductor nanostructures. The metal gate stack has a work function metal layer continuously wrapped around each of the semiconductor nanostructures.

In accordance with some embodiments, a method for forming a semiconductor device structure is provided. The method includes forming multiple sacrificial nanostructures and multiple semiconductor nanostructures laid out in an alternating manner on a substrate. The method also includes forming a first epitaxial structure on side edges of the semiconductor nanostructures and partially removing the first epitaxial structure to expose side edges of an upper group of the semiconductor nanostructures. The method further includes forming an isolation layer covering the first epitaxial structure and forming a second epitaxial structure on the side edges of the upper group of the semiconductor nanostructures. In addition, the method includes removing the sacrificial nanostructures and forming a metal gate stack wrapped around the semiconductor nanostructures. The metal gate stack has a continuous work function metal layer wrapped around each of the semiconductor nanostructures.

In accordance with some embodiments, a semiconductor device structure is provided. The semiconductor device structure includes a first semiconductor nanostructure and a second semiconductor nanostructure above the first semiconductor nanostructure. The semiconductor device structure also includes first epitaxial structures sandwiching the first semiconductor nanostructure and second epitaxial structures sandwiching the second semiconductor nanostructure. The second epitaxial structures and the first epitaxial structures are oppositely doped. The semiconductor device structure further includes a metal gate stack wrapped around the first semiconductor nanostructure and the second semiconductor nanostructure. The metal gate stack has a work function layer continuously surrounding the first semiconductor nanostructure and the second semiconductor nanostructure. The work function layer is a titanium-containing layer. In addition, the semiconductor device structure includes a dielectric layer surrounding the metal gate stack and covering the first epitaxial structure and the second epitaxial structure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for forming a semiconductor device structure, comprising:
forming a fin structure over a substrate, wherein the fin structure has a plurality of sacrificial nanostructures and a plurality of semiconductor nanostructures laid out in an alternating manner;
forming a dummy gate stack extending across a portion of the fin structure;
partially removing the fin structure to form a recess exposing side edges of the sacrificial nanostructures and the semiconductor nanostructures;
forming a first epitaxial structure on the side edges of a lower group of the semiconductor nanostructures;
forming an isolation layer over the first epitaxial structure;
forming a second epitaxial structure on the side edges of an upper group of the semiconductor nanostructures, wherein the second epitaxial structure and the first epitaxial structure are oppositely doped;
removing the dummy gate stack and the sacrificial nanostructures to expose the semiconductor nanostructures; and
forming a metal gate stack wrapped around the semiconductor nanostructures, wherein the metal gate stack has a work function metal layer continuously wrapped around each of the semiconductor nanostructures.

2. The method for forming a semiconductor device structure as claimed in claim 1, wherein the formation of the metal gate stack comprises:
forming a first gate dielectric layer wrapped around each of the lower group of the semiconductor nanostructures before the formation of the work function metal layer of the metal gate stack; and
forming a second gate dielectric layer wrapped around each of the upper group of the semiconductor nanostructures before the formation of the work function metal layer of the metal gate stack.

3. The method for forming a semiconductor device structure as claimed in claim 2, further comprising:
forming the first gate dielectric layer wrapped around each of the semiconductor nanostructures;
forming a blocking layer covering a lower portion of the first gate dielectric layer wrapped around the lower group of the semiconductor nanostructures; and
modifying an upper portion of the first gate dielectric layer to turn the upper portion of the first gate dielectric layer into the second gate dielectric layer wrapped around the upper group of the semiconductor nanostructures.

4. The method for forming a semiconductor device structure as claimed in claim 3, further comprising:
partially removing the blocking layer to expose the upper portion of the first gate dielectric layer;
forming a modifying layer over the blocking layer to wrap around the upper portion of the first gate dielectric layer; and
removing the modifying layer and the blocking layer after the second gate dielectric layer is formed.

5. The method for forming a semiconductor device structure as claimed in claim 4, further comprising:
heating the modifying layer and the upper portion of the first gate dielectric layer to turn the upper portion of the first gate dielectric layer into the second gate dielectric layer.

6. The method for forming a semiconductor device structure as claimed in claim 1, wherein no work function layer is formed to replace the work function metal layer continuously wrapped around the upper group of the semiconductor nanostructures.

7. The method for forming a semiconductor device structure as claimed in claim 1, wherein the work function metal layer is a single work function layer.

8. The method for forming a semiconductor device structure as claimed in claim 1, further comprising:
forming a second work function metal layer over the work function metal layer, wherein the second work function metal layer is continuously wrapped around the upper group of the semiconductor nanostructures and the lower group of the semiconductor nanostructures.

9. The method for forming a semiconductor device structure as claimed in claim 1, wherein the sacrificial nanostructures are made of an oxide material.

10. The method for forming a semiconductor device structure as claimed in claim 1, further comprising:
forming inner spacers covering the side edges of the sacrificial nanostructures before the first epitaxial structure is formed.

11. A method for forming a semiconductor device structure, comprising:
forming a plurality of sacrificial nanostructures and a plurality of semiconductor nanostructures laid out in an alternating manner on a substrate;
forming a first epitaxial structure on side edges of the semiconductor nanostructures;
partially removing the first epitaxial structure to expose side edges of an upper group of the semiconductor nanostructures;
forming an isolation layer covering the first epitaxial structure;
forming a second epitaxial structure on the side edges of the upper group of the semiconductor nanostructures;
removing the sacrificial nanostructures; and
forming a metal gate stack wrapped around the semiconductor nanostructures, wherein the metal gate stack has a continuous work function metal layer wrapped around each of the semiconductor nanostructures.

12. The method for forming a semiconductor device structure as claimed in claim 11, further comprising:
forming a second continuous work function metal layer wrapped around the upper group of the semiconductor nanostructures and the lower group of the semiconductor nanostructures.

13. The method for forming a semiconductor device structure as claimed in claim 11, further comprising:
forming a first gate dielectric layer wrapped around a lower semiconductor nanostructure next to the first epitaxial structure; and
forming a second gate dielectric layer wrapped around an upper semiconductor nanostructure next to the second epitaxial structure.

14. The method for forming a semiconductor device structure as claimed in claim 11, wherein the first gate dielectric layer and the second gate dielectric layer are made of a same material and are simultaneously formed, and the method further comprises doping at least one of the first gate dielectric layer and the second gate dielectric layer.

15. The method for forming a semiconductor device structure as claimed in claim 11, wherein the first epitaxial structure and the second epitaxial structure are oppositely doped.

16. A semiconductor device structure, comprising:
a first semiconductor nanostructure;
a second semiconductor nanostructure above the first semiconductor nanostructure;
first epitaxial structures sandwiching the first semiconductor nanostructure;
second epitaxial structures sandwiching the second semiconductor nanostructure, wherein the second epitaxial structures and the first epitaxial structures are oppositely doped;
a metal gate stack wrapped around the first semiconductor nanostructure and the second semiconductor nanostructure, wherein the metal gate stack has a work function layer continuously surrounding the first semiconductor nanostructure and the second semiconductor nanostructure, and the work function layer is a titanium-containing layer; and
a dielectric layer surrounding the metal gate stack and covering the first epitaxial structure and the second epitaxial structure.

17. The semiconductor device structure as claimed in claim 16, wherein the first semiconductor nanostructure has a first thickness, the second semiconductor nanostructure has a second thickness, and the first thickness and the second thickness are different.

18. The semiconductor device structure as claimed in claim 16, further comprising:
a third semiconductor nanostructure sandwiched between the first epitaxial structures, wherein the metal gate stack is wrapped around the third semiconductor nanostructure, and the work function layer continuously surrounds the third semiconductor nanostructure.

19. The semiconductor device structure as claimed in claim 16, wherein the metal gate stack has a first gate dielectric layer and a second gate dielectric layer, the first gate dielectric layer is wrapped around the first semiconductor nanostructure, the second gate dielectric layer is wrapped around the second semiconductor nanostructure, and the first gate dielectric layer and the second gate dielectric layer are made of different materials.

20. The semiconductor device structure as claimed in claim 19, wherein each of the first gate dielectric layer and the second gate dielectric layer comprises a dielectric material, and one of the first gate dielectric layer and the second gate dielectric layer further comprises a modifying dopant.
